(19) United States
(12) Patent Application Publication
(10) Pub. No.: US 2021/0376563 A1
(43) Pub. Date: Dec. 2, 2021

(54) Semiconductor Side Emitting Laser Leadframe Package and Method of Producing Same

(71) Applicant: Excelitas Canada, Inc., Vaudreuil-Dorion (CA)

(72) Inventors: JinHan Ju, Kirkland (CA); Gabriel Charlebois, Vaudreuil-Dorion (CA)

(21) Appl. No.: 16/882,858

(22) Filed: May 26, 2020

(51) Int. Cl. H01S 5/022

(52) U.S. Cl. CPC H01S 5/02244; H01S 5/02256; H01S 5/02276

(57) ABSTRACT

A surface mount laser package for a side-looking semiconductor laser has a substantially planar leadframe with a component side and a board attach side. The component side has a conductive die attach pad and a plurality of wire bond pads. A laser die has an anode surface and a cathode surface, where the cathode surface is mounted to the conductive die attach pad. A plurality of bond wires span between the laser die anode surface and a wire bond pad. A molding encases the laser die and the plurality of bond wired on the component side of the leadframe and also lies between the conductive die attach pad and each of the wire bond pads within a plane of the leadframe. The conductive die attach pad has a metallization layer on the leadframe and each of the bond pads has a metallization layer on the leadframe.

### FIELD OF THE INVENTION

The present invention relates to electronic circuitry, and more particularly, is related to surface mount packaging for semiconductor emitters.

### BACKGROUND OF THE INVENTION

FIGS. 1A-1C show an exemplary existing surface mount design (SMD) package 100 for a side emitting laser array 140. For example, as shown in FIG. 1B, a current SMD package 100, is shown with an array die of four side emitting semiconductor lasers 140 mounted on a substrate 120, for example, a printed circuit board (PCB) or a ceramic. The PCB or ceramic substrate 120 may be relatively thick with respect to the overall height of the package 110, for example, on the order of 30% to 50% of the overall package height.

A plurality of wire bond pads 146 are attached to the substrate 120, and a plurality of bond wires 144 electrically connect the laser array die 140 to the wire bond pads 146. The wire bond pads may be connected to surface mount pads 170 at the bottom of the package 100, where through vias (not shown) provide an electrical connection between the wire bond pads 146 and the surface mount pads 170. The electronic components are encapsulated with a transparent resin 150, for example an epoxy. The current SMD package 100 may have inductance and resistance that are too high for some application, for example a LIDAR application where the lasers must rapidly discharge and recharge. Therefore, there is a need in the industry to overcome the deficiencies in this area.

### SUMMARY OF THE INVENTION

Embodiments of the present invention provide a semiconductor side emitting laser leadframe package and method for producing the same. Briefly described, the present invention is directed to a surface mount laser package for a side-looking semiconductor laser. The package has a substantially planar leadframe with a component side and a board attach side. The component side has a conductive die attach pad and a plurality of wire bond pads. A laser die has an anode surface and a cathode surface, where the cathode surface is mounted to the conductive die attach pad. A plurality of bond wires span between the laser die anode surface and a wire bond pad. A molding encases the laser die and the plurality of bond wired on the component side of the leadframe and also lies between the conductive die attach pad and each of the wire bond pads within a plane of the leadframe. The conductive die attach pad has a metallization layer on the leadframe and each of the bond pads has a metallization layer on the leadframe.

Other systems, methods and features of the present invention will be or become apparent to one having ordinary skill in the art upon examining the following drawings and detailed description. It is intended that all such additional systems, methods, and features be included in this description, be within the scope of the present invention and protected by the accompanying claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principals of the invention.

FIG. 1A is a schematic diagram of an exemplary existing surface mount design (SMD) package for a side emitting laser array shown from a perspective view.

FIG. 1B is a schematic diagram of the SMD package of FIG. 1A shown from a top view.

FIG. 1C is a schematic diagram of the SMD package of FIG. 1A shown from a front side view.

FIG. 2 is a schematic diagram of an exemplary first embodiment of a semiconductor side emitting laser leadframe package shown from a perspective view.

FIG. 3A shows a top down view of the first embodiment package of FIG. 2.

FIG. 3B shows the package of FIG. 2 from a side view.

FIG. 3C show an isolated view of the leadframe of FIG. 2 from a top down view.

FIG. 4 shows the side emitting laser diodes of the laser array die of FIG. 2 emitting a laser beam through the mold compound.

FIG. 5A shows a matrix of leadframes under the first embodiment.

FIG. 5B shows a laser die and bond wires attached to one leadframe of FIG. 5A.

FIG. 5C shows the matrix of leadframes of FIG. 5A with laser dies and wire bonds attached.

FIG. 6 is a flowchart of an exemplary embodiment of a method for forming a semiconductor side emitting laser leadframe package.

FIG. 7 is a schematic diagram of a 3 by 10 array of leadframes of FIG. 5A with laser dies and wire bonds attached.

### DETAILED DESCRIPTION

The following definitions are useful for interpreting terms applied to features of the embodiments disclosed herein, and are meant only to define elements within the disclosure.

As used within this disclosure, “substantially” means “very nearly” or to within normal manufacturing tolerances. For example, a substantially parallel surface may be parallel to within acceptable tolerances, or a substantially flat surface is flat to within a specified measure of flatness. Similarly, a substantially undisturbed laser beam refers to a laser beam that is not significantly or noticeably altered (distorted or diverted) beyond acceptable operating tolerances.

As used within this disclosure, Surface-mount technology (SMT) refers to the mounting of electrical components directly onto the surface of a printed circuit board (PCB). An electrical component mounted in this manner is referred to as a surface-mount device (SMD). A SMD may be contrasted with through-hole technology construction for mounting components to a PCB by inserting component pins through holes in a circuit board, in large part because SMT allows for increased manufacturing automation.

As used within this disclosure, “molding” refers to a transfer molded sealing compound with high pressure for encasing electronic components of an SMT electronic package. In contrast, encapsulation, refers to a covering compound, for example a self-leveling epoxy potting over the electronic components.

Reference will now be made in detail to embodiments of the present invention, examples of which are illustrated in the accompanying drawings. Wherever possible, the same reference numbers are used in the drawings and the description to refer to the same or like parts.

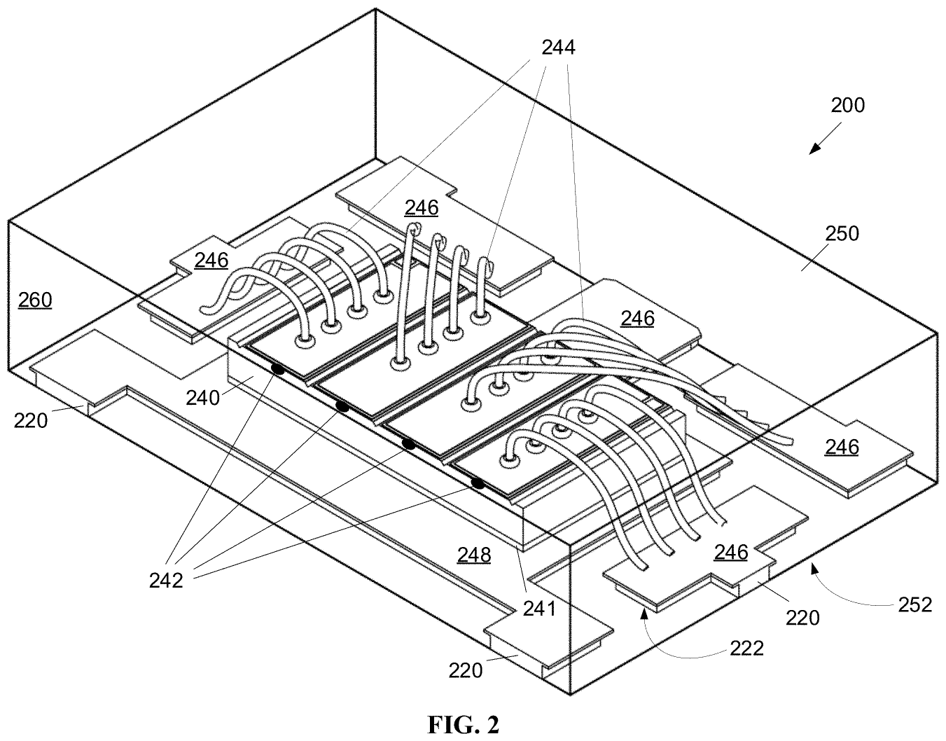

Exemplary embodiments of the present invention include devices and methods for producing SMD packages for one or more side emitting lasers. As shown in FIG. 2, an exemplary first embodiment 200 of the present invention includes a semiconductor side emitting laser die 240 having very low inductance and very low thermal resistance, at very low material and manufacturing cost in comparison with previous packages. The first exemplary embodiment includes a four channel laser die 240 attached on the very thin leadframe 220, gold or aluminum wires electrically connecting the die to the thin metal leadframe wire bond pads 246 and an encasing molding 250.

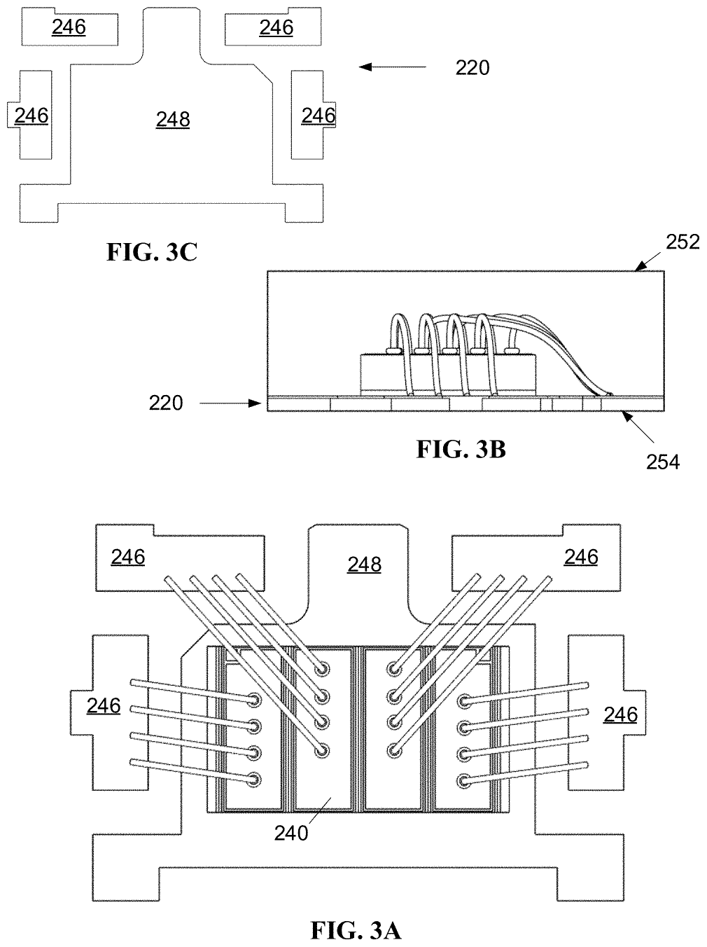

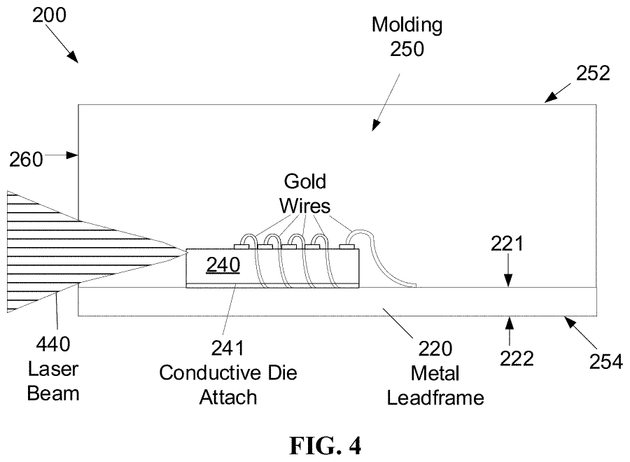

As shown by FIG. 4, under the first embodiment, the leadframe 220 is made of Nickel and plated with silver on a lead frame top surface 221 for gold wire bonding and laser die attach. A leadframe bottom surface 222 has a gold plating for mounting the package 200 on, for example, a PCB (not shown). In general, the bottom surface 254 of the package 200 is substantially coplanar with the leadframe bottom surface 222. Under the first embodiment, the leadframe thickness is on the order of about 65 microns thick to achieve very low inductance and very low thermal resistance. In alternative embodiments the leadframe thickness may be on the order of 50 microns to 250 microns thick. The laser die is attached to a conductive die pad 248 (FIG. 3C) on the metal leadframe 220 by thermally and electrically conductive material 241, for example, solder or epoxy.

Alternative embodiments of the package 200 may have a single side emitting laser diode instead of a laser diode array die 240 or may have an array die 240 with a different number of laser diodes, for example, two, eight, or sixteen, or more laser diodes.

FIG. 2 shows an exemplary first embodiment of a SMD package 200 having a laser array die 240 having four side emitter laser diodes, each laser diode having a side aperture 242 for emission of a laser beam in a direction substantially parallel to the leadframe 220 mounting surface. The leadframe 220 serves as a carrier for the laser die 240 and associated circuitry.

The package 200 includes an encasing molding 250, for example a molding material transparent to light emitted by the laser die array 240 encompassing the laser die 240 and the leadframe 220. Preferably, the molding material adheres well to the laser die and wire bonds and leadframe pads, is rigid enough to resist, for example, a temperature cycle test, the singulation process (described later), and surface polishing. For example, a desirable encasing molding material has a hardness greater than Shore D 70 at room temperature (23° C.), and light transmission of greater 90% for light of 905 nm wavelengths. In particular, the molding extends from a top portion 252 of the package 200 to a bottom surface 254 of the package 200, so that the molding surrounds all exposed surfaces of the leadframe 220 except for a leadframe bottom surface 222.

Additional circuitry associated with the laser die 240 may also be situated on the leadframe 220 encased by the molding 250, for example, a plurality of wire bond pads 246 formed as a metallization layer on the leadframe 220, and a plurality of bond wires 244 electrically connecting the laser array die 240 to the wire bond pads 246. In alternative embodiments, other circuit components may be encased within the molding 250, for example, capacitors, driver circuitry, and the like.

FIG. 3A shows a top down view of the first embodiment package 200. FIG. 3A shows the package 200 from a top view. FIG. 3B shows the package 200 from a side view. FIG. 3C show an isolated view of the leadframe 220, identifying the mounting surfaces 246, 248.

As shown by FIG. 4, the side emitting laser diodes of the laser array die 240 are oriented to emit laser beams 440 through the molding 250 so that the laser beams exit the package 200 through an egress surface 260 of the molding 250.

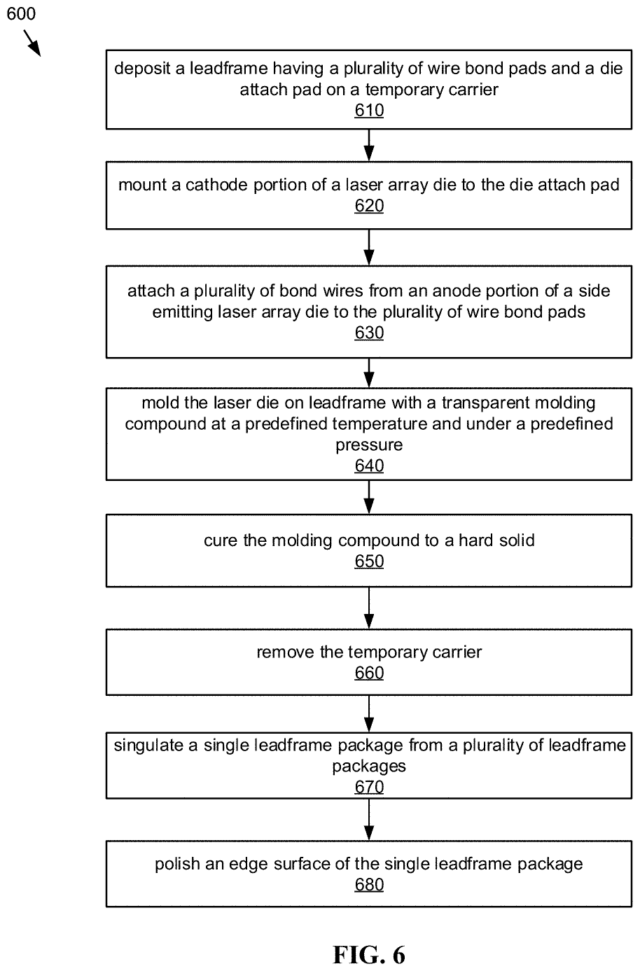

FIG. 6 is a flowchart of an exemplary embodiment of a method 600 for forming a semiconductor side emitting laser leadframe package. It should be noted that any process descriptions or blocks in flowcharts should be understood as representing modules, segments, portions of code, or steps that include one or more instructions for implementing specific logical functions in the process, and alternative implementations are included within the scope of the present invention in which functions may be executed out of order from that shown or discussed, including substantially concurrently or in reverse order, depending on the functionality involved, as would be understood by those reasonably skilled in the art of the present invention. The method of FIG. 6 is described with respect to the first embodiment of FIG. 2.

A leadframe 220 having a plurality of wire bond pads 246 and a die attach pad 248 is deposited on a temporary carrier (not shown), as shown by block 610. For example, the leadframe 220 may be removably attached to the temporary carrier via a removable adhesive. Alternatively, the temporary carrier itself may be a strip of removable adhesive material. In another alternative embodiment, the bottom surface of the 220 may be coated with a masking material that is removed during the manufacturing process to expose the leadframe 220 material and/or a thermally and/or electrically conductive metallization layer at the bottom of the leadframe 220. A cathode (bottom) portion of a laser array die 240 is mounted to the die attach pad 248, as shown by block 620. For example, the laser array die 240 cathode may be mounted to the die attach pad 248 with an electrically and thermally conductive material. A plurality of bond wires 244 spanning from an anode (top) portion of the side emitting laser array die 240 are attached to the plurality of wire bond pads 246, as shown by block 630. The laser die 240 is molded on and around the leadframe with a transparent molding compound 250 at a predefined temperature and under a predefined pressure, as shown by block 640. The molding compound 250 is cured to a hard solid, as shown by block 650. The temporary carrier is removed, as shown by block 660, so the leadframe 220 at the bottom surface of the package 200 is substantially coplanar with a bottom surface of the molding 250.

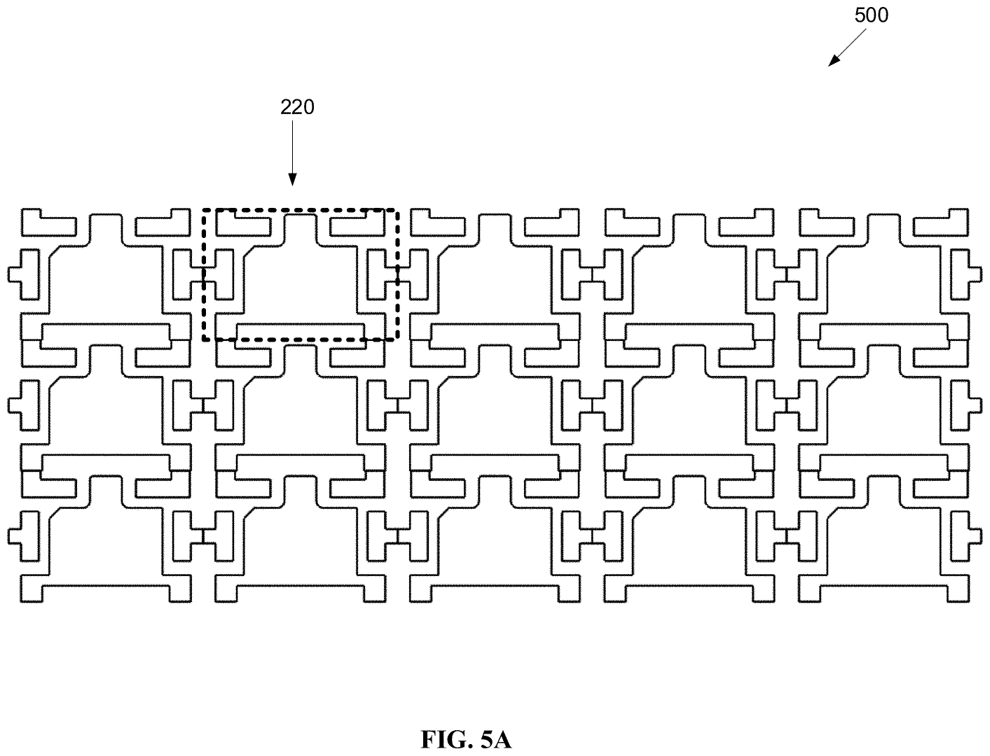

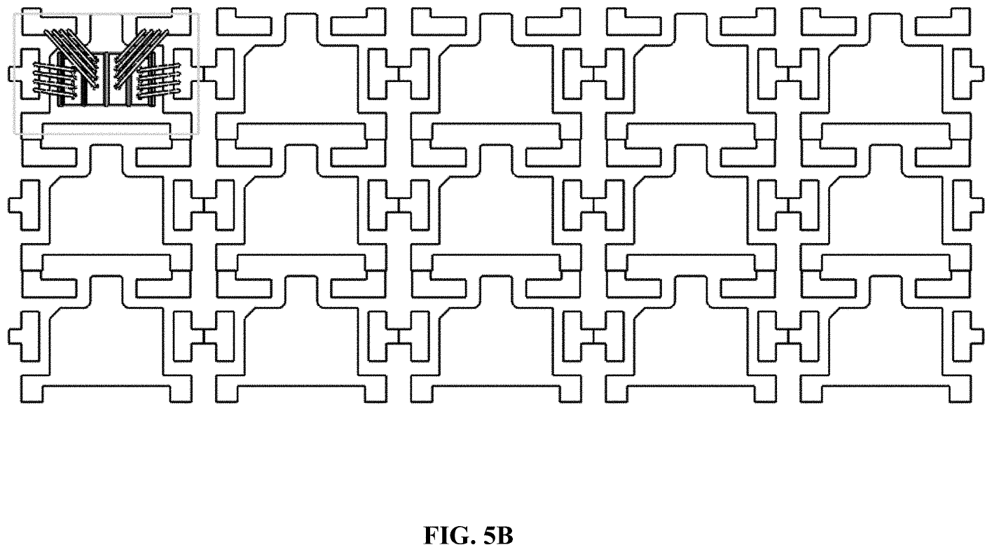

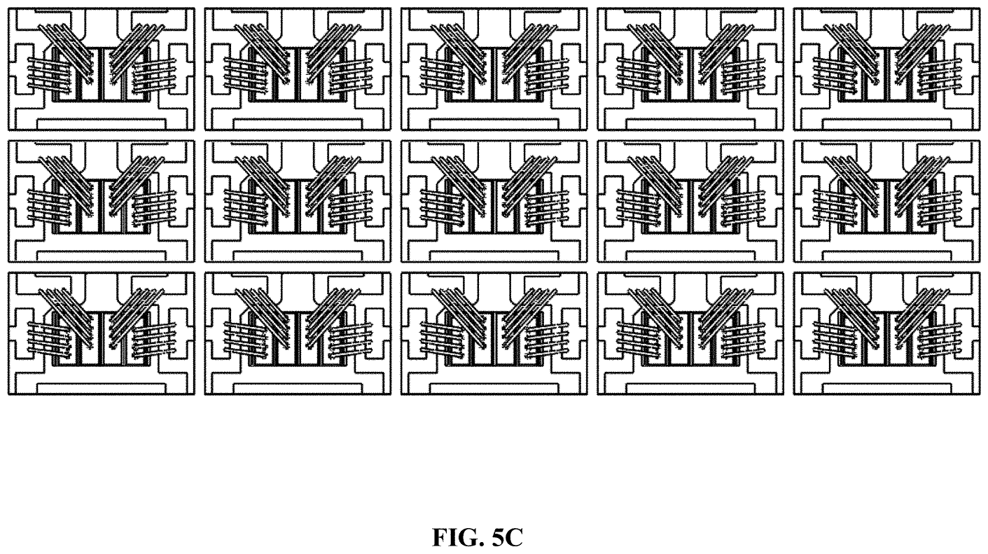

For manufacturing, the leadframe 220 may be one section of a matrix or array of leadframes 500, as shown by FIG. 5A, facilitating co-production of multiple packages 200 at once. While FIG. 5A shows a 3 by 5 matrix for clarity, in practice the matrix 500 may be considerably larger, for example, a metal leadframe strip matrix of 20 by 63 matrix yielding 1260 units per strip.

Returning to FIG. 6, a single leadframe package may be singulated from a plurality of leadframe packages, as shown by block 670. An edge surface of the single leadframe package is polished, as shown by block 680.

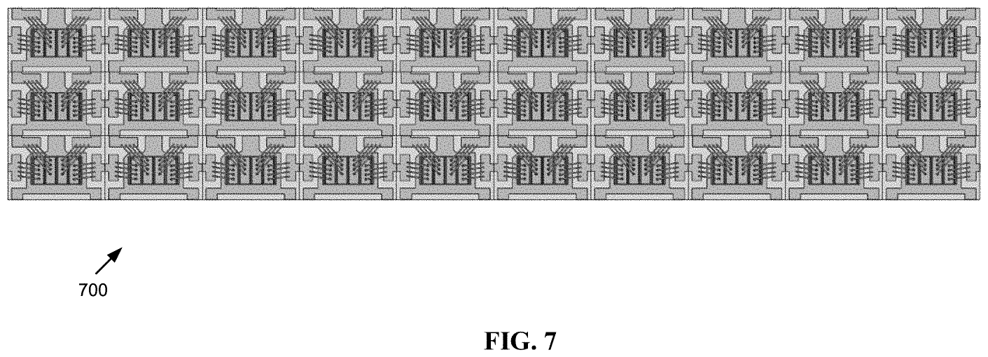

The laser die 240 is attached to each lead frame portion 220, as shown by FIG. 5B. Here, the bottom (cathode) of the laser die 240 (FIG. 2) is attached upon the leadframe 220 using an electrically and thermally conductive material. Gold bonding wires 244 (FIG. 2) are attached to an anode (top portion) of the laser die 240 to wire bond pads 246 (FIG. 2) on the leadframe 220 (FIG. 2). While FIG. 5B shows the attachment of a single laser die for clarity, in general the laser dies and wire bonds are attached to all of the lead frame portions during the same manufacturing step, as shown by FIG. 5C. The laser dies 240 are molded on leadframe 220, for example with a transfer molding machine, using a transparent molding compound at a predetermined temperature and under a predetermined pressure. The molding compound is cured at a predetermined temperature and time period to a hard solid. FIG. 7 shows an exemplary 3 by 10 matrix 700.

After the molding compound has cured, the packages 200 may be singulated into individual units. After singulation, at least one surface 260 of the molding may be polished to allow emission of a laser beam from the laser array die 240, for example, an egress surface 260 of the molding adjacent to an emitter of the laser array die 240.

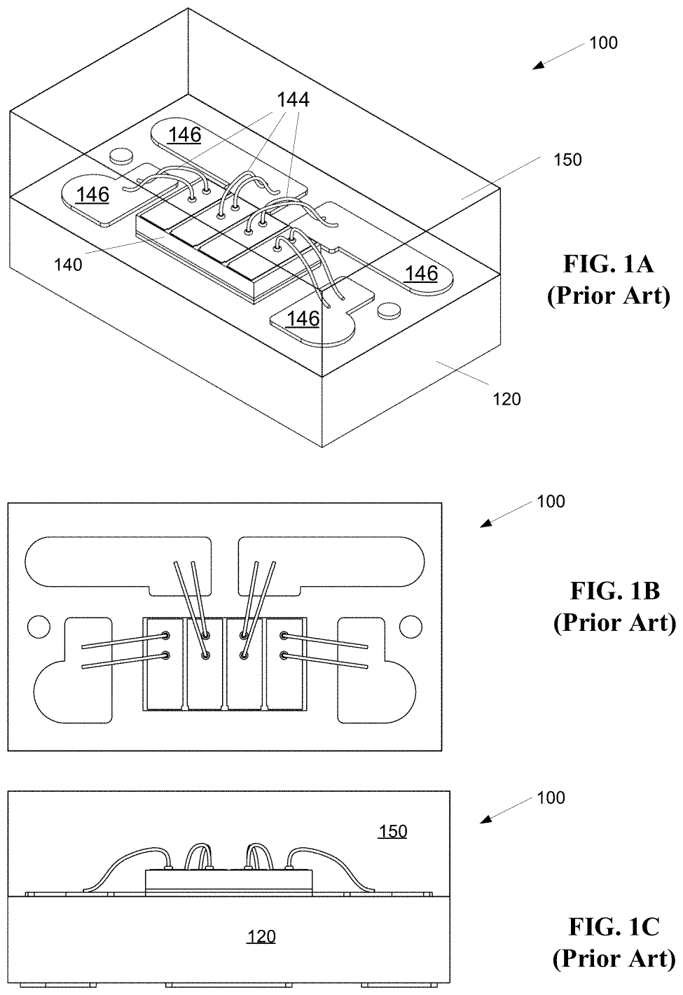

The present embodiments have several advantages over the previous semiconductor laser packages 100 (FIGS. 1A-1C). For example, the package 200 under the present embodiment may be considerably smaller than the previous package 100. Typically, the previous package 100 for a 4-channel laser on a PCB substrate has a footprint on the order of 3.5 mm by 2.0 mm and a height of 1.65 mm. In contrast, under the present embodiment a 4-channel laser on a leadframe package 200 footprint may have a footprint area of 2.6 mm by 1.7, that is 4.4 mm², comparing with a 7.0 mm² footprint of the previous package, or 63% of previous package footprint. The height of the package 200 is on the order of 0.60 mm compared with 1.65 mm for the previous package 100, or 36% of the height of the previous package 100.

Because the leadframe 220 of the present embodiment package 200 is considerably thinner than the PCB or ceramic substrate 120 of the previous package 100, under the present embodiments, the thinner leadframe 220 necessarily results in shorter electrical connection distances between the laser die 240 and the host PCB (not shown) than the distance between the laser die 140 and the host PCB in the previous package. The longer electrical connection distances of the previous package 100 result in greater inductance and thermal resistance in comparison with the package 200 of the present embodiments. The thermal resistance of the previous package 100 is on the order of at least 20° C./W, whereas the thermal resistance of the package 200 under the present embodiment may be on the order of less than 5° C./W, or less than 25% of the thermal resistance compared with the previous package 100. In practical terms, this may result in higher reliability and longer laser lifetime for the present embodiment package 200.

Also due to the shorter electrical connection distances of the package 200 under the current embodiments, the inductance may be decreased, for example, from on the order of greater than 1.3 nH to less than 0.3 nH, or less than 25% of the inductance of the previous package 100. This may facilitate laser performance improvement of the present package, for example, shorter laser pulse width.

In addition, there may be significant cost savings for producing the present embodiments in comparison with the previous package 100, for example, by eliminating the fabrication of a PCB substrate 120, the use of less expensive components, and the use of less material overall due to the smaller size. The leadframe design makes possible of making hundreds and thousands of small packages in very short cycle time.

In summary, it will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A surface mount laser package for a side-looking semiconductor laser, comprising:
a substantially planar leadframe with a component side and a board attach side, the component side further comprising a conductive die attach pad and a plurality of wire bond pads;
a laser die comprising an anode surface and a cathode surface, the cathode surface mounted to the conductive die attach pad;
a plurality of bond wires, each bond wire comprising a first end in electrical communication with the laser die anode surface and a second end in electrical communication with a wire bond pad of the plurality of wire bond pads; and
a molding encasing the laser die and the plurality of bond wired on the component side of the leadframe and further disposed between the conductive die attach pad and each of the plurality of wire bond pads within a plane of the leadframe.

2. The surface mount laser package of claim 1, wherein the conductive die attach pad comprises a metallization layer on the leadframe and each of the plurality of wire bond pads comprises a metallization layer on the leadframe.

3. The surface mount laser package of claim 1, wherein the leadframe has a thickness on the order of 65 microns.

4. The surface mount laser package of claim 1, wherein the molding encasing is comprises a thermosetting polymer material.

5. The surface mount laser package of claim 4, wherein the thermosetting polymer material transparent to the light from the laser die.

6. The surface mount laser package of claim 4, wherein the thermosetting polymer material transparent is compatible to the transfer molding process. The molding material has to be hard enough after curing for singulating the molded matrix into individual units, and for surface polishing the light emitting side.

7. The surface mount laser package of claim 1, wherein a bottom surface of the laser package comprises a surface of cured molding and the leadframe component side.

8. A method for forming a semiconductor side emitting laser leadframe package, comprising the steps of:
depositing a leadframe comprising a plurality of wire bond pads and a die attach pad on a temporary carrier;
mounting a cathode portion of a laser array die to the die attach pad;
attaching a plurality of bond wires from an anode portion of a side emitting laser array die to the plurality of wire bond pads;
molding the laser die on leadframe with a transparent molding compound, at a predefined temperature and under a predefined pressure;
curing the molding compound to a hard solid; and
removing the temporary carrier.

9. The method of claim 8, wherein the laser array die cathode is mounted to the die attach pad with an electrically and thermally conductive material.

10. The method of claim 8, wherein the leadframe is a section of a leadframe matrix

11. The method of claim 8, wherein the leadframe is attached to the temporary carrier via an adhesive.

12. The method of claim 8, further comprising the step of polishing a surface of the molding adjacent to an emitter of the laser array die.

13. The method of claim 8, wherein the transparent molding compound comprises a thermosetting polymer material.

14. The method of claim 8, further comprising the step of singulating a single leadframe package from a plurality of leadframe packages.

15. The method of claim 8, further comprising the step of polishing an edge surface of the single leadframe package.
